(19) United States
(12) Patent Application Publication
(10) Pub. No.: US 2024/0262979 A1
(43) Pub. Date: Aug. 8, 2024

(54) THERMALLY-CONDUCTIVE SHEET AND THERMALLY-CONDUCTIVE SHEET PRODUCTION METHOD

(71) Applicant: DEXERIALS CORPORATION, Shimotsuke-shi, Tochigi (JP)

(72) Inventors: Yuma SATO, Shimotsuke-shi, Tochigi (JP); Yusuke KUBO, Shimotsuke-shi, Tochigi (JP)

(73) Assignee: DEXERIALS CORPORATION, Shimotsuke-shi, Tochigi (JP)

(21) Appl. No.: 18/567,857

(22) PCT Filed: Jun. 8, 2022
(86) PCT No.: PCT/JP2022/023095

§ 371 Date: Dec. 7, 2023

(30) Foreign Application Priority Data
Jun. 16, 2021 (JP) 2021-099914
Oct. 28, 2021 (JP) 2021-176215
Nov. 4, 2021 (JP) 2021-180253
Jun. 8, 2022 (JP) 2022-092767

(51) Int. Cl. C08K 3/38; C08J 5/18; C08K 7/04; C08L 83/04

(52) U.S. Cl. CPC C08K 3/38; C08J 5/18; C08K 7/04; C08L 83/04; C08K 2003/385; C08K 2201/001; C08L 2203/206

(57) ABSTRACT

A thermally conductive sheet including: a cured material of a composition including: a binder resin, an anisotropically thermally conductive filler, and an additional thermally conductive filler other than the anisotropically thermally conductive filler. The thermally conductive sheet satisfies condition 1: a tack force of the thermally conductive sheet is 80 gf or higher; and condition 2: a bleed amount of the binder resin is 0.20 g or less after the thermally conductive sheet, which has a size of 25 mm×25 mm and a thickness of 1 mm, is left standing for 48 hours at 125° C. in a state of being compressed by 40%.

### TECHNICAL FIELD

The present technology relates to a thermally conductive sheet and a method for producing a thermally conductive sheet. The present application claims priority on the basis of Japanese patent applications filed in Japan: No. 2021-099914, filed on Jun. 16, 2021; No. 2021-176215, filed on Oct. 28, 2021; No. 2021-180253, filed on Nov. 4, 2021; and No. 2022-092767, filed on Jun. 8, 2022. These applications are incorporated into the present application by reference.

### BACKGROUND TECHNOLOGY

Semiconductor elements are becoming denser and are being implemented more frequently as electronic devices attain higher performances. It is thus becoming important to more efficiently dissipate heat generated by electronic components composing the electronic devices. For example, in a semiconductor device, to efficiently dissipate heat, electronic components are attached to a cooling fan, a radiator plate, or another heat sink via a thermally conductive sheet. As the thermally conductive sheet, one in which an inorganic filler or another filling material is contained (dispersed) in a silicone resin is in wide use (for example, see Patent Documents 1 and 2).

Further improvement in thermal conductance is in demand for heat-dissipating members such as thermally conductive sheets. For example, increasing the filling rate of an inorganic filler blended into a matrix of a binder resin or the like is being considered for the purpose of increasing the thermal conductivity of the thermally conductive sheet. However, increasing the filling rate of the inorganic filler risks impairing the flexibility of the thermally conductive sheet and risks the inorganic filler falling out in powder form. There is thus a limit to increasing the filling rate of the inorganic filler in the thermally conductive sheet.

As the inorganic filler, for example, alumina, aluminum nitride, and aluminum hydroxide can be mentioned. Flaky particles of boron nitride, graphite, or the like; carbon fiber; or the like is also sometimes filled in the matrix for the purpose of increasing thermal conductance. This is for the anisotropic thermal conductance provided by the flaky particles, the carbon fiber, or the like. For example, it is known that carbon fiber has a thermal conductance of approximately 600 to 1,200 W/m·K in the direction of the fibers. It is also known that flaky particles of boron nitride have a thermal conductance of approximately 110 W/m·K in the planar direction and approximately 2 W/m·K in the direction perpendicular to the planar direction. In this manner, it is known that carbon fiber and flaky particles have anisotropic thermal conductance. Making the direction of the carbon fibers and the planar direction of the flaky particles the same as the thickness direction, which is a heat transfer direction, of the thermally conductive sheet—that is, orienting the carbon fibers and the flaky particles in the thickness direction of the thermally conductive sheet—can dramatically improve the thermal conductance of the thermally conductive sheet.

In an electronic device using the thermally conductive sheet, from a viewpoint of an effect on the aesthetics of the periphery of an electronic component or the like using the thermally conductive sheet or on the conductivity of an electrical contact, it is desirable to prevent bleeding (residue) of a binder resin (for example, a silicone resin) composing the thermally conductive sheet from being scattered and from sticking to the electrical contact. The bleeding of the binder resin in the thermally conductive sheet arises due to, for example, a bias in the blending ratio of an addition-reaction-type silicone resin. The bleeding of the binder resin also affects the tackiness of the thermally conductive sheet and thus also affects the quality of adhesion (temporary fixation) of the thermally conductive sheet to the object the sheet is adhered to (heat generator). With the technology disclosed in Patent Documents 1 and 2, it is difficult to provide a thermally conductive sheet that has excellent adhesion to a heat generator and can suppress excessive bleeding of a binder resin.

### CITATION LIST

### Patent Documents

Patent document 1: JP 2012-201106 A
Patent document 2: WO 2019/026745 A1

### SUMMARY OF INVENTION

### Problem to be Solved by Invention

The present technology is proposed in view of such conventional circumstances and provides a thermally conductive sheet that has excellent adhesion to a heat generator and can suppress excessive bleeding of a binder resin.

### Means to Solve the Problem

The thermally conductive sheet as in the present technology is made of a cured product of a composition containing: a binder resin; an anisotropically thermally conductive filler; and another thermally conductive filler other than the anisotropically thermally conductive filler. Moreover, the thermally conductive sheet meets the following conditions 1 and 2:
[Condition 1]: The tack force of the thermally conductive sheet is 80 gf or higher.
[Condition 2]: The bleed amount of the binder resin after the thermally conductive sheet—of a size of 25 mm×25 mm and a thickness of 1 mm—is left standing for 48 hours at 125° C. in a state of being compressed by 40% is 0.20 g or less.

A method for producing a thermally conductive sheet as in the present technology has: a step A of preparing a thermally conductive composition containing a binder resin, an anisotropically thermally conductive filler, and a thermally conductive filler other than the anisotropically thermally conductive filler; a step B of extruding the thermally conductive composition and afterward curing such to obtain a pillar-shaped cured material; and a step C of cutting, in a direction substantially perpendicular to the length direction of the pillar, the pillar-shaped cured material to a predetermined thickness to obtain the thermally conductive sheet. Moreover, the thermally conductive sheet meets the following conditions 1 and 2:
[Condition 1]: The tack force of the thermally conductive sheet is 80 gf or higher.
[Condition 2]: The bleed amount of the binder resin after the thermally conductive sheet—of a size of 25 mm×25 mm and a thickness of 1 mm—is left standing for 48 hours at 125° C. in a state of being compressed by 40% is 0.20 g or less.

### Effect of the Invention

The present technology can provide a thermally conductive sheet that has excellent adhesion to a heat generator and can suppress excessive bleeding of a binder resin.

### BRIEF DESCRIPTION OF THE DRAWINGS

FIG. 1 is a sectional view illustrating one example of a thermally conductive sheet.

FIG. 2 is a perspective view schematically illustrating a boron nitride flake whose crystal shape is hexagonal that is one example of an anisotropically thermally conductive filler.

FIG. 3 is a sectional view illustrating one example of a semiconductor device in which the thermally conductive sheet is applied.

[FIG. 4] (A) in FIG. 4 is a sectional view illustrating a state in which the thermally conductive sheet is interposed between compression jigs. (B) in FIG. 4 is a plan view illustrating a state in which the thermally conductive sheet is placed on the lower jig.

[FIG. 5] (A) in FIG. 5 is a plan view illustrating the state in which the thermally conductive sheet is interposed between the compression jigs. (B) in FIG. 5 is a side view illustrating the state in which the thermally conductive sheet is interposed between the compression jigs.

FIG. 6 is a diagram for describing a method of evaluating whether the thermally conductive sheet slides off when the thermally conductive sheet is placed on an aluminum plate and tilted 90°.

### DESCRIPTION OF THE EMBODIMENTS

In the present description, the average particle size (D50) of an anisotropically thermally conductive filler or another thermally conductive filler refers to, in a situation in which the entire particle size distribution of the anisotropically thermally conductive filler or the other thermally conductive filler is defined as 100%, the particle size at which, when the cumulative curve of the particle size values is found starting from the low end of the particle size distribution, the cumulative value is 50%. In the present description, the grain size distribution (particle size distribution) is found on the basis of volume. As a method for measuring the grain size distribution, for example, a method using a machine of a laser-diffraction type for measuring grain size distribution can be mentioned.

### <Thermally Conductive Sheet>

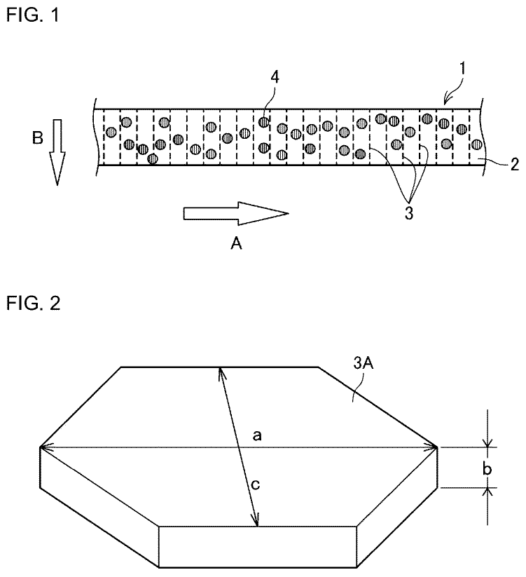

FIG. 1 is a sectional view illustrating one example of a thermally conductive sheet 1 as in the present technology. The thermally conductive sheet 1 is made of a cured material of a composition including: a binder resin 2, an anisotropically thermally conductive filler 3, and another thermally conductive filler 4 other than the anisotropically thermally conductive filler 3. In the thermally conductive sheet 1, the anisotropically thermally conductive filler 3 and the other thermally conductive filler 4 are dispersed in the binder resin 2, and the anisotropically thermally conductive filler 3 is oriented in a thickness direction B of the thermally conductive sheet 1.

Here, the anisotropically thermally conductive filler 3 being oriented in the thickness direction B of the thermally conductive sheet 1 signifies that, for example, of the entirety of the anisotropically thermally conductive filler 3 in the thermally conductive sheet 1, the proportion of the anisotropically thermally conductive filler 3 having the long axis oriented in the thickness direction B of the thermally conductive sheet 1 is 50% or higher. However, this proportion may also be 55% or higher, 60% or higher, 65% or higher, 70% or higher, 80% or higher, 90% or higher, 95% or higher, or 99% or higher.

The anisotropically thermally conductive filler 3 is a thermally conductive filler that is anisotropic in terms of shape. As the anisotropically thermally conductive filler 3, a thermally conductive filler having a long axis, a short axis, and a thickness (for example, a flaky thermally conductive filler) can be mentioned. A flaky thermally conductive filler is a thermally conductive filler that has a long axis, a short axis, and a thickness; has a high aspect ratio (long axis/thickness), and has isotropic thermal conductance in a planar direction including the long axis. The short axis of the flaky thermally conductive filler refers to the length of the shortest portion of the flaky thermally conductive filler, this being in a direction, in the plane including the long axis of the flaky thermally conductive filler, intersecting the midpoint of the long axis of the flaky thermally conductive filler. The thickness of the flaky thermally conductive filler refers to a value that is the average of ten measurement points of the thickness along the plane including the long axis of the flaky thermally conductive filler. The aspect ratio of the anisotropically thermally conductive filler 3 is not limited in particular and can be selected as appropriate according to the purpose. For example, the aspect ratio of the anisotropically thermally conductive filler 3 can be made to be in a range of 10 to 100 but may be in a range of 20 to 50 or 15 to 40. The long axis, the short axis, and the thickness of the anisotropically thermally conductive filler 3 can be measured by, for example, a microscope, a scanning electron microscope (SEM), or a grain size analyzer.

The other thermally conductive filler 4 is a thermally conductive filler other than the anisotropically thermally conductive filler 3—that is, a thermally conductive filler that is not anisotropic in terms of shape.

The thermally conductive sheet 1 meets the following conditions 1 and 2:
[Condition 1]: The tack force of the thermally conductive sheet 1 is 80 gf or higher.
[Condition 2]: The bleed amount of the binder resin 2 after the thermally conductive sheet 1—of a size of 25 mm×25 mm and a thickness of 1 mm—is left standing for 48 hours at 125° C. in a state of being compressed by 40% is 0.20 g or less.

Regarding condition 1, from a viewpoint of the adhesion of the thermally conductive sheet 1 to a heat generator that is the object the sheet is adhered to, the tack force of the thermally conductive sheet 1 is 80 gf or higher but may also be 85 gf or higher, 88 gf or higher, 92 gf or higher, or in a range of 80 to 92 gf. The method for measuring the tack force of the thermally conductive sheet 1 is the same as the method in the examples described below.

Regarding condition 2, in consideration of the circumstances (environment) in which the thermally conductive sheet 1 is used, the bleed amount of the binder resin 2 after the thermally conductive sheet 1 is left standing for 48 hours at 125° C. in a state of being compressed by 40% is 0.20 g or less but may also be 0.19 g or less, 0.18 g or less, 0.17 g or less, or 0.15 g or less. From a viewpoint of meeting condition 1, the bleed amount of the binder resin 2 after the thermally conductive sheet 1 is left standing for 48 hours at 125° C. in the state of being compressed by 40% is preferably a predetermined amount or more and may be 0.15 g or more, in a range of 0.15 to 0.20 g, or in a range of 0.15 to 0.19 g. The method for measuring the bleed amount of the binder resin 2 in the thermally conductive sheet 1 is the same as the method in the examples described below. For example, the bleed amount of the binder resin 2 is measured after the thermally conductive sheet 1—25 mm×25 mm, 1—mm thick—is left standing for 48 hours at 125° C. in the state of being compressed by 40%.

In this manner, the thermally conductive sheet 1 meets conditions 1 and 2 described above and thus has excellent adhesion to the heat generator and can suppress excessive bleeding of the binder resin 2. From a viewpoint of increasing thermal conductivity, the thermally conductive sheet 1 preferably further meets the following condition 3 in addition to conditions 1 and 2 described above:
[Condition 3]: The bulk thermal conductance of the thermally conductive sheet 1 is 9.5 W/m·K or higher.

Regarding condition 3, the thermally conductive sheet 1 preferably has a bulk thermal conductance of 9.5 W/m·K or higher. However, the bulk thermal conductance may be 9.9 W/m·K or higher, 10.5 W/m·K or higher, 10.6 W/m·K or higher, 11.3 W/m·K or higher, 11.4 W/m·K or higher, 12.3 W/m·K or higher, 13.1 W/m·K or higher, in a range of 9.5 to 13.1 W/m·K, or in a range of 9.9 to 13.1 W/m·K. The bulk thermal conductance of the thermally conductive sheet 1 can be measured by the method described in the examples described below.

The effective thermal conductance in the thickness direction B of the thermally conductive sheet 1 may be 7.5 W/m·K or higher, 8.0 W/m·K or higher, 8.3 W/m·K or higher, 8.5 W/m·K or higher, 9.1 W/m·K or higher, 9.2 W/m·K or higher, 9.3 W/m·K or higher, 10.5 W/m·K or higher, 11.1 W/m·K or higher, in a range of 7.5 to 9.2 W/m·K, or in a range of 7.5 to 11.1 W/m·K. The effective thermal conductance of the thermally conductive sheet 1 can be measured by the method described in the examples described below.

The thickness of the thermally conductive sheet 1 is not limited in particular and can be selected as appropriate according to the purpose. For example, the thickness of the thermally conductive sheet can be made to be 0.05 mm or more and can also be made to be 0.1 mm or more. The upper limit of the thickness of the thermally conductive sheet can be made to be 5 mm or less but may be 4 mm or less or 3 mm or less. From a viewpoint of handling of the thermally conductive sheet 1, the thickness of the thermally conductive sheet 1 is preferably made to be 0.1 to 4 mm. The thickness of the thermally conductive sheet 1 can be found by, for example, measuring the thickness B of the thermally conductive sheet 1 at any five locations and obtaining the arithmetic mean value thereof.

In the thermally conductive sheet 1, the amount of change of the thermal resistance value measured at a compression ratio of 10% after the sheet is left standing for 1,000 hours at 150° C. with respect to the thermal resistance value measured at a compression ratio of 10% immediately after production is preferably within 10% but may be 8.7% or less, 8.6% or less, 8.2% or less, 8.1% or less, 8.0% or less, 7.8% or less, 7.7% or less, 7.6% or less, 7.4% or less, 7.1% or less, 6.7% or less, in a range of 6.7 to 10%, in a range of 6.7% to 8.7%, or in a range of 6.7 to 8.2%. The amount of change being within these ranges tends to reduce fluctuations in the thermal resistance value despite usage over a long time. The amount of change in the thermal resistance value of the thermally conductive sheet 1 can be measured by the method described in the examples described below.

In the thermally conductive sheet 1, the thermal resistance value measured at a compression ratio of 10% immediately after production is, for example, 1.27° C.·cm²/W or lower but may also be 1.19° C.·cm²/W or lower, 1.16° C.·cm²/W or lower, 1.05° C.·cm²/W or lower, 1.04° C.·cm²/W or lower, 0.92° C.·cm²/W or lower, 0.88° C.·cm²/W or lower, or in a range of 0.88 to 1.27° C.·cm²/W.

In the thermally conductive sheet 1, the thermal resistance value measured at a compression ratio of 10% after the sheet is left standing for 1,000 hours at 150° C. may be, for example, 1.36° C.·cm²/W or lower, 1.27° C.·cm²/W or lower, 1.25° C.·cm²/W or lower, 1.14° C.·cm²/W or lower, 1.13° C.·cm²/W or lower, 1.12° C.·cm²/W or lower, 1.00° C.·cm²/W or lower, 0.95° C.·cm²/W or lower, or in a range of 0.95 to 1.36° C.·cm²/W.

From a viewpoint of flexibility, in the thermally conductive sheet 1, the compression ratio measured using a load of 3 kgf/cm² after the sheet is left standing for 1,000 hours at 150° C. is preferably 20% or higher but may be 21% or higher, 22% or higher, 23% or higher, 25% or higher, 26% or higher, 28% or higher, in a range of 20 to 28%, or in a range of 21 to 28%. In this manner, the thermally conductive sheet 1 can maintain favorable flexibility even after being left standing for 1,000 hours at 150° C. The compression ratio using a load of 3 kgf/cm² of the thermally conductive sheet 1 can be measured by the method described in the examples described below.

In terms of the hardness of the thermally conductive sheet 1, for example, a Shore type OO hardness immediately after production (initial Shore hardness) is preferably in a range of 20 to 90 but may be in a range of 40 to 70 or 55 to 60. In the thermally conductive sheet 1, the Shore type OO hardness after the sheet is left standing for 1,000 hours at 150° C. is preferably in a range of 40 to 95 but may be in a range of 65 to 90. The hardness of the thermally conductive sheet 1 being in these ranges makes the thermally conductive sheet 1 conform more favorably to the object the sheet is adhered to. Facilitating surface contact between the thermally conductive sheet and the object the sheet is adhered to enables more effective thermal conduction. The hardness of the thermally conductive sheet 1 can be measured by the method described in the examples described below.

The thermally conductive sheet 1 preferably has a high breakdown voltage. The breakdown voltage of when the thickness is 1 mm may be 7.0 kV or higher, 7.5 kV or higher, 8.1 kV or higher, 8.4 kV or higher, 8.5 kV or higher, 8.6 kV or higher, 8.7 kV or higher, 9.0 kV or higher, or in a range of 8.1 to 9.0 kV. The breakdown voltage of the thermally conductive sheet 1 can be measured by the method in the examples described below.

Specific examples of the components of the thermally conductive sheet 1 are described below.

### <Binder Resin>

The binder resin 2 is for holding the anisotropically thermally conductive filler 3 and the other thermally conductive filler 4 in the thermally conductive sheet 1. The binder resin 2 is selected according to the mechanical strength, thermal resistance, electrical properties, and other characteristics required of the thermally conductive sheet 1. The binder resin 2 can be selected from among a thermoplastic resin, a thermoplastic elastomer, and a thermosetting resin.

As the thermoplastic resin, polyethylene, polypropylene, an ethylene-propylene copolymer, or another ethylene-α-olefin copolymer; polymethylpentene, polyvinyl chloride, polyvinylidene chloride, polyvinyl acetate, an ethylene-vinyl acetate copolymer, polyvinyl alcohol, polyvinyl acetal, polyvinylidene fluoride, polytetrafluoroethylene, or another fluoropolymer; polyethylene terephthalate, polybutylene terephthalate, polyethylene naphthalate, polystyrene, polyacrylonitrile, a styrene-acrylonitrile copolymer, an acrylonitrile-butadiene-styrene copolymer (ABS) resin, a polyphenylene-ether copolymer (PPE) resin, a modified PPE resin, an aliphatic polyamide, an aromatic polyamide, a polyimide, a polyamide-imide, a polymethacrylate, a polymethyl methacrylate ester, or another polymethacrylate ester; a polyacrylate; a polycarbonate; polyphenylene sulfide; polysulfone; polyethersulfone; polyether nitrile; polyether ketone; a polyketone; a liquid-crystal polymer; a silicone resin; an ionomer; and the like can be mentioned.

As the thermoplastic elastomer, a styrene-butadiene block copolymer or a hydrogenated product thereof, a styrene-isoprene block copolymer or a hydrogenated product thereof, a styrene thermoplastic elastomer, an olefin thermoplastic elastomer, a vinyl chloride thermoplastic elastomer, a polyester thermoplastic elastomer, a polyurethane thermoplastic elastomer, a polyamide thermoplastic elastomer, and the like can be mentioned.

As the thermosetting resin, a cross-linked rubber, an epoxy resin, a phenol resin, a polyimide resin, an unsaturated polyester resin, a diallylphthalate resin, and the like can be mentioned. As specific examples of the cross-linked rubber, natural rubber, acrylic rubber, butadiene rubber, isoprene rubber, styrene-butadiene copolymer rubber, nitrile rubber, hydrogenated nitrile rubber, chloroprene rubber, ethylene-propylene copolymer rubber, chlorinated polyethylene rubber, chlorosulfonated polyethylene rubber, butyl rubber, halogenated butyl rubber, fluororubber, urethane rubber, and silicone rubber can be mentioned.

As the binder resin 2, for example, from a viewpoint of adhesion between the heat-generating surface of the heat generator (for example, an electronic component) and a heat-sink surface, a silicone resin is preferable. As the silicone resin, for example, a two-part addition-reaction-type silicone resin made of a main agent, which has a silicone having an alkenyl group (polyorganosiloxane) as the main component and which contains a curing catalyst, and a curing agent having a hydrosilyl group (Si—H group) can be used. As the silicone having an alkenyl group, a polyorganosiloxane having at least two alkenyl groups in one molecule can be used. As one example, a polyorganosiloxane having a vinyl group can be used. The curing catalyst is a catalyst for accelerating an addition reaction between an alkenyl group in a silicone having the alkenyl group and a hydrosilyl group in a curing agent having the hydrosilyl group. As the curing catalyst, a catalyst well known as a catalyst used in a hydrosilylation reaction can be mentioned. For example, a platinum-group curing catalyst—for example, platinum, rhodium, palladium, or another platinum-group metal alone or platinum chloride or the like—can be used. As the curing agent having a hydrosilyl group, for example, a polyorganosiloxane having a hydrosilyl group (organohydrogenpolysiloxane having, in one molecule, at least two hydrogen atoms directly bonded to a silicon atom) can be used.

In particular, from a viewpoint of the thermally conductive sheet 1 having excellent adhesion to the heat generator and being able to suppress excessive bleeding of the binder resin 2, it is preferable to use a binder resin 2 that is an addition-reaction-type silicone resin made of a polyorganosiloxane having an alkenyl group in one molecule and of an organohydrogenpolysiloxane having, in one molecule, a hydrogen atom directly bonded to a silicon atom, the blending ratio between the polyorganosiloxane and the organohydrogenpolysiloxane satisfying the following equation 1:

Number of moles of hydrogen atoms directly bonded to silicon atoms/number of moles of alkenyl groups=0.40 to 0.60 Equation 1:

In equation 1, the number of moles of hydrogen atoms directly bonded to silicon atoms refers to the number of moles of hydrogen atoms directly bonded to the silicon atoms in the organohydrogenpolysiloxane having a hydrogen atom directly bonded to a silicon atom. In equation 1, the number of moles of alkenyl groups refers to the number of moles of alkenyl groups in the polyorganosiloxane having an alkenyl group. In the binder resin 2, the mole ratio expressed in equation 1 (also referred to as “Si—H/alkenyl group ratio” below) being 0.40 or greater tends to suppress the bleed amount of the binder resin 2, and the thermally conductive sheet 1 more easily meets condition 2 described above. In the binder resin 2, the mole ratio expressed in equation 1 being 0.60 or less tends to improve the tack force of the thermally conductive sheet 1, and condition 1 described above is more easily met. In the binder resin 2, the mole ratio expressed in equation 1 may be in a range of 0.45 to 0.58.

The polyorganosiloxane having an alkenyl group may have a kinematic viscosity at 23° C. in a range of 10 to 100,000 mm²/s or 500 to 50,000 mm²/s. When the kinematic viscosity at 23° C. of the polyorganosiloxane having an alkenyl group is 10 mm²/s or higher, the storage stability of the composition that is obtained tends to be more favorable. When the kinematic viscosity at 23° C. of the polyorganosiloxane having an alkenyl group is 100,000 mm²/s or lower, the extensibility of the composition that is obtained tends to be higher. The kinematic viscosity of the polyorganosiloxane having an alkenyl group signifies a value measured using an Ostwald viscometer. One type alone of a polyorganosiloxane having an alkenyl group may be used, or two or more types with different viscosities (kinematic viscosities) may be used together.

The content of the binder resin 2 in the thermally conductive sheet 1 is not limited in particular and can be selected as appropriate according to the purpose. For example, the content of the binder resin 2 in the thermally conductive sheet 1 can be made to be 30% by volume or higher but may be 32% by volume or higher, 34% by volume or higher, or 36% by volume or higher. The upper limit of the content of the binder resin 2 in the thermally conductive sheet 1 can be made to be 60% by volume or lower but may be 50% by volume or lower, 40% by volume or lower, 38% by volume or lower, or 37% by volume or lower. In particular, from a viewpoint of meeting conditions 1 and 2 described above, the content of the binder resin 2 in the thermally conductive sheet 1 can be made to be in a range of 30 to 38% by volume but may be in a range of 32 to 36% by volume. One type alone of a binder resin 2 may be used, or two or more types may be used together.

In particular, in the thermally conductive sheet 1, the content of the addition-reaction-type silicone resin whose mole ratio expressed in equation 1 is 0.40 to 0.60 is preferably 80% by volume or higher relative to the total amount of the binder resin 2 but may be 90% by volume or higher, 95% by volume or higher, 99% by volume or higher, or substantially 100%.

### <Anisotropically Thermally Conductive Filler>

The material of the anisotropically thermally conductive filler 3 is not limited in particular. For example, boron nitride (BN), mica, alumina, aluminum nitride, silicon carbide, silica, zinc oxide, and molybdenum disulfide can be mentioned. From a viewpoint of thermal conductance, boron nitride is preferable. One type alone of an anisotropically thermally conductive filler 3 may be used, or two or more types may be used together.

FIG. 2 is a perspective view schematically illustrating a boron nitride flake 3A whose crystal shape is hexagonal that is one example of the anisotropically thermally conductive filler 3. In FIG. 2, a represents the long axis of the boron nitride flake 3A, b represents the thickness of the boron nitride flake 3A, and c represents the short axis of the boron nitride flake 3A. As the anisotropically thermally conductive filler 3, from a viewpoint of thermal conductance, as illustrated in FIG. 2, it is preferable to use a boron nitride flake 3A whose crystal shape is hexagonal. In the present technology, by using a flaky thermally conductive filler (for example, boron nitride flakes 3A) that is less expensive than a spherical thermally conductive filler (for example, spherical boron nitride) as the anisotropically thermally conductive filler 3, a thermally conductive sheet 1 can be obtained that achieves both low cost and excellent thermal characteristics (high thermal conductance).

The average particle size of the anisotropically thermally conductive filler 3 can be selected as appropriate according to the purpose. From a viewpoint of improving the thermal conductivity of the thermally conductive sheet 1, the average particle size of the anisotropically thermally conductive filler 3 in the thermally conductive sheet 1 is 15 μm or greater but may also be 20 μm or greater, 25 μm or greater, 30 μm or greater, 35 μm or greater, or 40 μm or greater. From a viewpoint of improving the thermal conductivity of the thermally conductive sheet 1, the average particle size of the anisotropically thermally conductive filler 3 in the thermally conductive sheet 1 may be in a range of 30 to 60 μm, 30 to 50 μm, 35 to 55 μm, or 35 to 45 μm.

The content of the anisotropically thermally conductive filler 3 in the thermally conductive sheet 1 can be selected as appropriate according to the purpose. From a viewpoint of condition 2 described above, the content of the anisotropically thermally conductive filler 3 in the thermally conductive sheet 1 preferably exceeds 20% by volume but may be 21% by volume or more, 23% by volume or more, 25% by volume or more, or 26% by volume or more. From a viewpoint of condition 1 described above, the content of the anisotropically thermally conductive filler 3 in the thermally conductive sheet 1 is preferably less than 30% by volume but may be 28% by volume or less or 27% by volume or less. The content of the anisotropically thermally conductive filler 3 in the thermally conductive sheet 1 may be in a range of 23 to 27% by volume, 23 to 25% by volume, or 25 to 27% by volume.

### <Other Thermally Conductive Filler>

The other thermally conductive filler 4 includes spherical, powdered, granular, and other thermally conductive fillers. From a viewpoint of thermal conductivity of the thermally conductive sheet 1, the material of the other thermally conductive filler 4 is preferably, for example, a ceramic filler. As specific examples, aluminum oxide (alumina, sapphire), aluminum nitride, aluminum hydroxide, zinc oxide, boron nitride, zirconia, silicon carbide, and the like can be mentioned. One type alone of another thermally conductive filler 4 may be used, or two or more types (two or more types of thermally conductive fillers with different average particle sizes) may be used together.

In particular, in consideration of, for example, viewpoints of the thermal conductance of the thermally conductive sheet 1 and the specific gravity of the thermally conductive sheet 1, the other thermally conductive filler 4 is preferably one or more types, including at least alumina, from among alumina, aluminum nitride, zinc oxide, and aluminum hydroxide. Aluminum nitride and alumina may be used together, or aluminum nitride, alumina, and zinc oxide may be used together.

From a viewpoint of the specific gravity of the thermally conductive sheet 1, the average particle size of the aluminum nitride can be made to be less than 30 μm but may be 0.1 to 10 μm, 0.5 to 5 μm, 1 to 3 μm, or 1 to 2 μm. From a viewpoint of the specific gravity of the thermally conductive sheet 1, the average particle size of the alumina can be made to be 0.1 to 10 μm but may be 0.1 to 8 μm, 0.1 to 7 μm, or 0.1 to 3 μm. From a viewpoint of the specific gravity of the thermally conductive sheet 1, the average particle size of the zinc oxide can be made to be, for example, 0.01 to 5 μm but may be 0.03 to 3 μm or 0.05 to 2 μm.

The content of the other thermally conductive filler 4 in the thermally conductive sheet 1 can be selected as appropriate according to the purpose. The content of the other thermally conductive filler 4 in the thermally conductive sheet 1 can be made to be 10% by volume or more but may be 15% by volume or more, 20% by volume or more, 25% by volume or more, 30% by volume or more, or 35% by volume or more. The upper limit of the content of the other thermally conductive filler 4 in the thermally conductive sheet 1 can be made to be 50% by volume or less but may be 45% by volume or less or 40% by volume or less. The content of the other thermally conductive filler 4 in the thermally conductive sheet 1 may be in a range of 30 to 50% by volume or 35 to 45% by volume.

When, for example, using aluminum nitride particles, alumina particles, and zinc oxide particles together as the other thermally conductive filler 4, in the thermally conductive sheet 1, the content of the aluminum nitride particles is preferably made to be 10 to 25% by volume (in particular, 17 to 23% by volume), the content of the alumina particles is preferably made to be 10 to 25% by volume (in particular, 17 to 23% by volume), and the content of the zinc oxide particles is preferably made to be 0.1 to 5% by volume (in particular, 0.5 to 3% by volume).

From a viewpoint of meeting conditions 1 and 2 described above, the total content of the anisotropically thermally conductive filler 3 and the other thermally conductive filler 4 in the thermally conductive sheet 1 preferably exceeds 61% by volume but may be 64% by volume or more or 66% by volume or more. From a viewpoint of meeting conditions 1 and 2 described above, the total content of the anisotropically thermally conductive filler 3 and the other thermally conductive filler 4 in the thermally conductive sheet 1 is preferably made to be 68% by volume or less but may be 67% by volume or less, 66% by volume or less, or 65% by volume or less. From a viewpoint of the thermally conductive sheet 1 meeting conditions 1 and 2 described above, the total content of the anisotropically thermally conductive filler 3 and the other thermally conductive filler 4 in the thermally conductive sheet 1 can be made to be in a range of 64 to 68% by volume but may be in a range of 64 to 66% by volume.

The thermally conductive sheet 1 may further contain another component other than the components described above within a range of not impairing the effects of the present technology. As the other component, for example, a coupling agent, a dispersant, a curing accelerator, a retardant, a tackifier, a plasticizer, a flame retardant, an antioxidant, a stabilizer, a colorant, a solvent, and the like can be mentioned. For example, from a viewpoint of further improving the dispersion of the anisotropically thermally conductive filler 3 and the other thermally conductive filler 4, the thermally conductive sheet 1 may use an anisotropically thermally conductive filler 3 treated using a coupling agent and/or another thermally conductive filler 4 treated using a coupling agent.

### <Method for Producing Thermally Conductive Sheet>

The method for producing the thermally conductive sheet 1 has the following steps A, B, and C.

### <Step A>

At step A, the anisotropically thermally conductive filler 3 and the other thermally conductive filler 4 are dispersed in the binder resin 2. This produces a thermally conductive composition containing the binder resin 2, the anisotropically thermally conductive filler 3, and the other thermally conductive filler 4. The thermally conductive composition can be prepared by uniformly mixing in, by a known method, the binder resin 2, the anisotropically thermally conductive filler 3, and the other thermally conductive filler 4, and, as necessary, the other component described above.

### <Step B>

At step B, the thermally conductive composition prepared at step A is extruded and afterward cure to obtain a pillar-shaped cured material (molded block). The method of extrusion is not limited in particular and can be adopted from among various known extrusion methods as appropriate according to the viscosity of the thermally conductive composition, the characteristics required of the thermally conductive sheet 1, and the like. In the extrusion method, when extruding the thermally conductive composition from a die, the binder resin 2 in the thermally conductive composition flows, and the anisotropically thermally conductive filler 3 is oriented along the flow direction.

The size and shape of the pillar-shaped cured material obtained at step B can be determined according to the size of the thermally conductive sheet 1 that is sought. For example, a rectangular parallelepiped with a cross section having a vertical size of 0.5 to 15 cm and a horizontal size of 0.5 to 15 cm can be mentioned. The length of the rectangular parallelepiped can be determined, as necessary.

### <Step C>

At step C, the pillar-shaped cured material obtained at step B is cut to a predetermined thickness in the length direction of the pillar to obtain the thermally conductive sheet 1. The anisotropically thermally conductive filler 3 is exposed on the front surface (cut surface) of the thermally conductive sheet 1 obtained at step C. The cutting method is not limited in particular and can be selected as appropriate from among known slicing devices according to the size and mechanical strength of the pillar-shaped cured material. When the molding method is extrusion, some anisotropically thermally conductive fillers 3 may be oriented in the extrusion direction. Thus, the direction in which the pillar-shaped cured material is cut is preferably 60 to 120 degrees relative to the extrusion direction, more preferably in a direction of 70 to 100 degrees, and further preferably in a direction of 90 degrees (substantially perpendicular). The direction in which the pillar-shaped cured material is cut is not limited in particular other than as above and can be selected as appropriate according to, for example, the usage purpose of the thermally conductive sheet 1.

In this manner, the method for producing the thermally conductive sheet having steps A, B, and C provides a thermally conductive sheet 1 meeting conditions 1 and 2 described above.

The method for producing the thermally conductive sheet 1 is not limited to the example described above. For example, after step C, a step D of pressing the cut surface may be further provided. By being further provided with the pressing step D, the front surface of the thermally conductive sheet 1 obtained at step C is made smoother, and adhesion to other members can be further improved. As the method of pressing, a pair of press devices made of a flat plate and a press head having a flat surface can be used. Pressing may also be by pinch rollers. The pressing pressure can be made to be, for example, 0.1 to 100 MPa. To further increase the effects of pressing and to shorten the pressing time, the pressing is preferably performed at or above the glass transition temperature (Tg) of the binder resin 2. For example, the pressing temperature can be made to be 0 to 180° C. but may be within a temperature range of room temperature (for example, 25° C.) to 100° C. or 30 to 100° C.

### <Electronic Device>

By, for example, being disposed between a heat generator and a heat dissipator, the thermally conductive sheet 1 can be made into an electronic device (thermal device) having a structure of being disposed between the heat generator and the heat dissipator to release heat generated by the heat generator to the heat dissipator. The electronic device has at least the heat generator, the heat dissipator, and the thermally conductive sheet 1 but may further have other members, as necessary. In this manner, the electronic device applying the thermally conductive sheet 1 interposes the thermally conductive sheet 1 between the heat generator and the heat dissipator. Thus, high thermal conductivity is realized by the thermally conductive sheet 1. At the same time, adhesion of the thermally conductive sheet 1 to the heat generator is excellent, and excessive bleeding of the binder resin 2 from the thermally conductive sheet 1 can be suppressed.

The heat generator is not limited in particular. For example, a CPU, a GPU (graphics processing unit), a DRAM (dynamic random-access memory), a flash memory, or another integrated circuit device and a transistor, a resistor, or another electronic component that generates heat in an electrical circuit can be mentioned. The heat generator also includes components that receive optical signals, such as an optical transceiver in a communication device.

The heat dissipator is not limited in particular. For example, a heat sink, a heat spreader, or another component used in combination with an integrated circuit device, a transistor, an optical-transceiver housing, or the like can be mentioned. As the material of the heat sink and the heat spreader, for example, copper, aluminum, and the like can be mentioned. The heat dissipator may be a component other than a heat spreader or a heat sink as long as it conducts and diffuses to the outside the heat generated from the heat source. For example, a radiator, a cooler, a die pad, a printed board, a cooling fan, a Peltier element, a heat pipe, a vapor chamber, a metal cover, a housing, and the like can be mentioned. The heat pipe is a hollow structure of, for example, a cylindrical, substantially cylindrical, or flattened cylindrical shape.

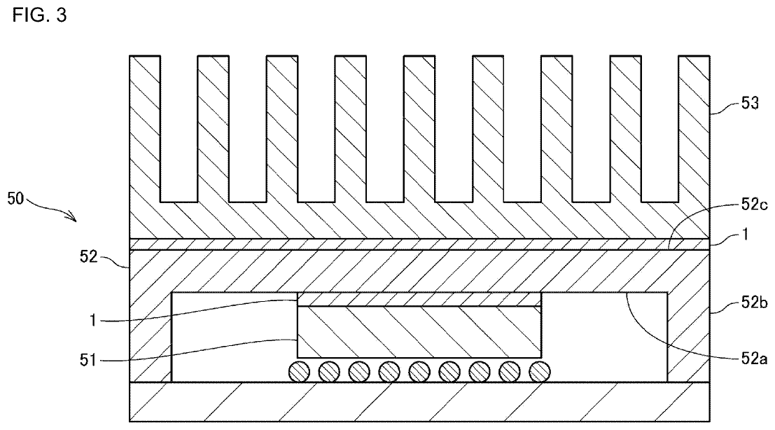

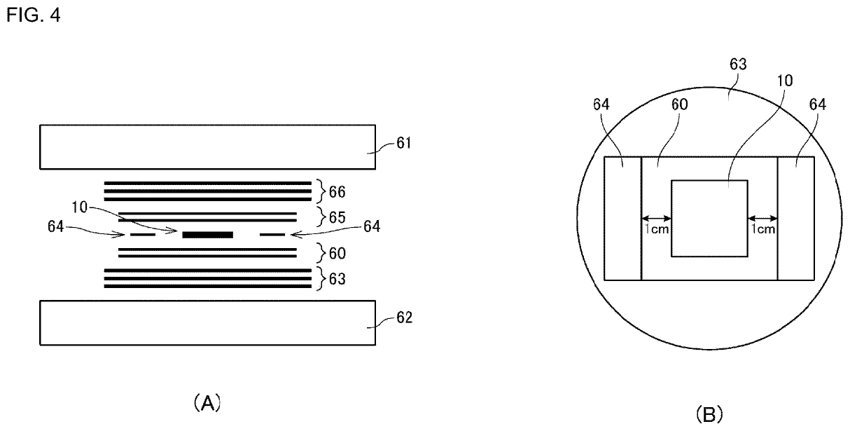

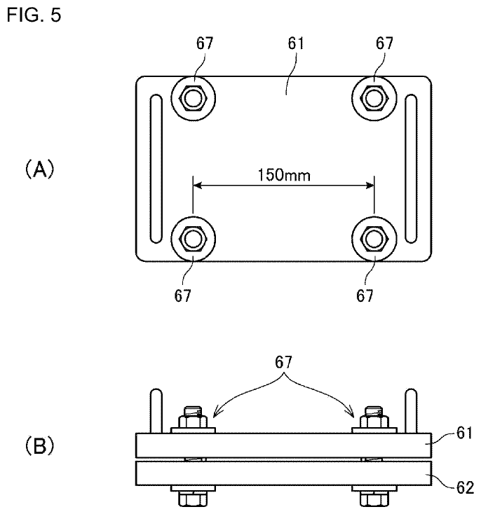

FIG. 3 is a sectional view illustrating one example of a semiconductor device in which the thermally conductive sheet is applied. For example, as illustrated in FIG. 3, the thermally conductive sheet 1 is mounted in a semiconductor device 50 built-in in various electronic devices and is interposed between a heat generator and a heat dissipator. The semiconductor device 50 illustrated in FIG. 3 is provided with an electronic component 51, a heat spreader 52, and the thermally conductive sheet 1. The thermally conductive sheet 1 is interposed between the heat spreader 52 and the electronic component 51. The thermally conductive sheet 1 being interposed between the heat spreader 52 and a heat sink 53 configures a heat-dissipating member that dissipates heat of the electronic component 51 together with the heat spreader 52. The mounting location of the thermally conductive sheet 1 is not limited to between the heat spreader 52 and the electronic component 51 or between the heat spreader 52 and the heat sink 53 and can be selected as appropriate according to the configuration of the electronic device or semiconductor device. The heat spreader 52 is formed in, for example, a rectangular plate shape and has a main surface 52a, which faces the electronic component 51, and a sidewall 52b, which is erected along the outer periphery of the main surface 52a. On the heat spreader 52, the thermally conductive sheet 1 is provided on the main surface 52a surrounded by the sidewall 52b, and the heat sink 53 is provided on another surface 52c, which is on the opposite side of the main surface 52a, via the thermally conductive sheet 1.

Embodiments of the thermally conductive sheet and the method of producing a thermally conductive sheet as in the present technology are described above. However, various configurations other than the embodiments described above can also be adopted. Examples of such embodiments are noted below.

### (Note 1)

A thermally conductive sheet made of a cured material of a composition containing: a binder resin, an anisotropically thermally conductive filler, and another thermally conductive filler other than the anisotropically thermally conductive filler, the sheet meeting the following conditions 1 and 2:
[Condition 1]: The tack force of the thermally conductive sheet is 80 gf or higher.
[Condition 2]: The bleed amount of the binder resin after the thermally conductive sheet—of a size of 25 mm×25 mm and a thickness of 1 mm—is left standing for 48 hours at 125° C. in a state of being compressed by 40% is 0.20 g or less.

### (Note 2)

The thermally conductive sheet of note 1, wherein the binder resin is an addition-reaction-type silicone resin;
the addition-reaction-type silicone resin is made of a polyorganosiloxane having an alkenyl group in one molecule and an organohydrogenpolysiloxane having, in one molecule, a hydrogen atom directly bonded to a silicon atom; and
the of the blending ratio polyorganosiloxane and the organohydrogenpolysiloxane satisfies the following equation 1:

$$Number of moles of hydrogen \\ atoms directly bonded to silicon atoms / number \\ of moles of alkenyl groups = 0.4 to 0.6 \qquad Equation 1$$

### (Note 3)

The thermally conductive sheet of note 1 or 2, wherein the content of the binder resin is 30 to 38% by volume.

### (Note 4)

The thermally conductive sheet of any among notes 1 to 3, wherein the content of the anisotropically thermally conductive filler is 22 to 29% by volume.

### (Note 5)

The thermally conductive sheet of any among notes 1 to 4, wherein the anisotropically thermally conductive filler is boron nitride, and
the other thermally conductive filler is one or more types, including at least alumina, from among alumina, aluminum nitride, zinc oxide, and aluminum hydroxide.

### (Note 6)

The thermally conductive sheet of any among notes 1 to 5, wherein the anisotropically thermally conductive filler is boron nitride flakes, and
the boron nitride flakes are oriented in the thickness direction of the thermally conductive sheet.

### (Note 7)

The thermally conductive sheet of any among notes 1 to 6, wherein the sheet further meets the following condition 3:
[Condition 3]: The bulk thermal conductance of the thermally conductive sheet is 9.5 W/m·K or higher.

### (Note 8)

The thermally conductive sheet of any among notes 1 to 7, wherein the amount of change of the thermal resistance value measured at a compression ratio of 10% after the sheet is left standing for 1,000 hours at 150° C. relative to the thermal resistance value measured at a compression ratio of 10% immediately after production is within 10%.

### (Note 9)

The thermally conductive sheet of any among notes 1 to 8, wherein the compression ratio measured using a load of 3 kgf/cm² after the sheet is left standing for 1,000 hours at 150° C. is 20% or higher.

### (Note 10)

A method for producing a thermally conductive sheet, the method having: a step A of preparing a thermally conductive composition containing a binder resin, an anisotropically thermally conductive filler, and a thermally conductive filler other than the anisotropically thermally conductive filler;
a step B of extruding the thermally conductive composition and afterward curing such to obtain a pillar-shaped cured material; and
a step C of cutting, in a direction substantially perpendicular to the length direction of the pillar, the pillar-shaped cured material to a predetermined thickness to obtain the thermally conductive sheet; wherein
the thermally conductive sheet meets the following conditions 1 and 2:
[Condition 1]: The tack force of the thermally conductive sheet is 80 gf or higher.
[Condition 2]: The bleed amount of the binder resin after the thermally conductive sheet—of a size of 25 mm×25 mm and a thickness of 1 mm—is left standing for 48 hours at 125° C. in a state of being compressed by 40% is 0.20 g or less.

### (Note 11)

The method for producing a thermally conductive sheet of note 10, wherein the binder resin is an addition-reaction-type silicone resin;
the addition-reaction-type silicone resin is made of a polyorganosiloxane having an alkenyl group in one molecule and of an organohydrogenpolysiloxane having, in one molecule, a hydrogen atom directly bonded to a silicon atom; and
the blending ratio of the polyorganosiloxane and the organohydrogenpolysiloxane satisfies the following equation 1:

$$Number of moles of hydrogen \\ atoms directly bonded to silicon atoms / number \\ of moles of alkenyl groups = 0.4 to 0.6 \qquad Equation 1$$

### (Note 12)

The method for producing a thermally conductive sheet of note 10 or 11, wherein the sheet further meets the following condition 3:
[Condition 3]: The bulk thermal conductance of the thermally conductive sheet is 9.5 W/m·K or higher.

### (Note 13)

An electronic device, provided with: a heat generator;
a heat dissipator; and
the thermally conductive sheet of any among notes 1 to 9 interposed between the heat generator and the heat dissipator.

### EXAMPLES

Examples of the present technology are described below. The present technology is not limited to these examples.

### Example 1

A thermally conductive composition was prepared by uniformly mixing: at 32% by volume, a silicone resin whose Si—H/alkenyl group ratio expressed in equation 1 described above is 0.45; at 27% by volume, boron nitride flakes whose crystal shape is hexagonal (D50 of 40 μm, aspect ratio of 20 to 50); at 20% by volume, aluminum nitride (D50 of 1.2 μm); at 20% by volume, spherical alumina particles (D50 of 2 μm); and at 1% by volume, zinc oxide particles (D50 of 0.1 μm). This thermally conductive composition was, by an extrusion method, poured into a die having an internal space of a rectangular parallelepiped shape (opening: 50 mm×50 mm) and heated for 4 hours in a 60° C. oven to form a pillar-shaped cured material (molded block). A polyethylene terephthalate release film was affixed to the inner surface of the die so the release-treated surface was on the inner side. Using a slicer, the obtained pillar-shaped cured material was cut (sliced), in a direction substantially orthogonal to the length direction of the pillar, into a 1 mm thick sheet shape. This provided a thermally conductive sheet in which the boron nitride flakes are oriented in the thickness direction of the sheet.

### Example 2

In example 2, a thermally conductive sheet was obtained using the same method as example 1 other than preparing a thermally conductive composition by uniformly mixing: at 32% by volume, a silicone resin whose Si—H/alkenyl group ratio expressed in equation 1 described above is 0.58; at 27% by volume, boron nitride flakes whose crystal shape is hexagonal (D50 of 40 μm, aspect ratio of 20 to 50); at 20% by volume, aluminum nitride (D50 of 1.2 μm); at 20% by volume, spherical alumina particles (D50 of 2 μm); and at 1% by volume, zinc oxide particles (D50 of 0.1 μm).

### Example 3

In example 3, a thermally conductive sheet was obtained using the same method as example 1 other than preparing a thermally conductive composition by uniformly mixing: at 34% by volume, a silicone resin whose Si—H/alkenyl group ratio expressed in equation 1 described above is 0.45; at 25% by volume, boron nitride flakes whose crystal shape is hexagonal (D50 of 40 μm, aspect ratio of 15 to 40); at 20% by volume, aluminum nitride (D50 of 1.2 μm); at 20% by volume, spherical alumina particles (D50 of 2 μm); and at 1% by volume, zinc oxide particles (D50 of 0.1 μm).

### Example 4

In example 4, a thermally conductive sheet was obtained using the same method as example 1 other than preparing a thermally conductive composition by uniformly mixing: at 36% by volume, a silicone resin whose Si—H/alkenyl group ratio expressed in equation 1 described above is 0.45; at 23% by volume, boron nitride flakes whose crystal shape is hexagonal (D50 of 40 μm, aspect ratio of 15 to 40); at 20% by volume, aluminum nitride (D50 of 1.2 μm); at 20% by volume, spherical alumina particles (D50 of 2 μm); and at 1% by volume, zinc oxide particles (D50 of 0.1 μm).

### Example 5

In example 5, a thermally conductive sheet was obtained using the same method as example 1 other than preparing a thermally conductive composition using boron nitride flakes whose crystal shape is hexagonal (D50 of 50 μm, aspect ratio of 25 to 60) instead of boron nitride flakes whose crystal shape is hexagonal (D50 of 40 μm, aspect ratio of 20 to 50).

### Example 6

In example 6, a thermally conductive sheet was obtained using the same method as example 2 other than preparing a thermally conductive composition using boron nitride flakes whose crystal shape is hexagonal (D50 of 50 μm, aspect ratio of 25 to 60) instead of boron nitride flakes whose crystal shape is hexagonal (D50 of 40 μm, aspect ratio of 20 to 50).

### Example 7

In example 7, a thermally conductive sheet was obtained using the same method as example 3 other than preparing a thermally conductive composition using boron nitride flakes whose crystal shape is hexagonal (D50 of 50 μm, aspect ratio of 20 to 50) instead of boron nitride flakes whose crystal shape is hexagonal (D50 of 40 μm, aspect ratio of 15 to 40).

### Example 8

In example 8, a thermally conductive sheet was obtained using the same method as example 4 other than preparing a thermally conductive composition using boron nitride flakes whose crystal shape is hexagonal (D50 of 50 μm, aspect ratio of 20 to 50) instead of boron nitride flakes whose crystal shape is hexagonal (D50 of 40 μm, aspect ratio of 15 to 40).

### Example 9

In example 9, a thermally conductive sheet was obtained using the same method as example 1 other than preparing a thermally conductive composition by uniformly mixing: at 33% by volume, a silicone resin whose Si—H/alkenyl group ratio expressed in equation 1 described above is 0.45; at 27% by volume, boron nitride flakes whose crystal shape is hexagonal (D50 of 40 μm, aspect ratio of 15 to 40); at 20% by volume, aluminum nitride (D50 of 1.2 μm); and at 20% by volume, spherical alumina particles (D50 of 2 μm).

### Example 10

In example 10, a thermally conductive sheet was obtained using the same method as example 1 other than preparing a thermally conductive composition by uniformly mixing: at 33% by volume, a silicone resin whose Si—H/alkenyl group ratio expressed in equation 1 described above is 0.45; at 27% by volume, boron nitride flakes whose crystal shape is hexagonal (D50 of 40 μm, aspect ratio of 15 to 40); at 30% by volume, aluminum nitride (D50 of 1.2 μm); and at 10% by volume, spherical alumina particles (D50 of 2 μm).

### Comparative Example 1

In comparative example 1, a thermally conductive sheet was obtained using the same method as example 1 other than preparing a thermally conductive composition by uniformly mixing: at 32% by volume, a silicone resin whose Si—H/alkenyl group ratio expressed in equation 1 described above is 0.33; at 27% by volume, boron nitride flakes whose crystal shape is hexagonal (D50 of 40 μm, aspect ratio of 10 to 30); at 20% by volume, aluminum nitride (D50 of 1.2 μm); at 20% by volume, spherical alumina particles (D50 of 2 μm); and at 1% by volume, zinc oxide particles (D50 of 0.1 μm).

### Comparative Example 2

In comparative example 2, a thermally conductive sheet was obtained using the same method as example 1 other than preparing a thermally conductive composition by uniformly mixing: at 32% by volume, a silicone resin whose Si—H/alkenyl group ratio expressed in equation 1 described above is 0.84; at 27% by volume, boron nitride flakes whose crystal shape is hexagonal (D50 of 40 μm, aspect ratio of 10 to 30); at 20% by volume, aluminum nitride (D50 of 1.2 μm); at 20% by volume, spherical alumina particles (D50 of 2 μm); and at 1% by volume, zinc oxide particles (D50 of 0.1 μm).

### Comparative Example 3

In comparative example 3, a thermally conductive sheet was obtained using the same method as example 1 other than preparing a thermally conductive composition by uniformly mixing: at 29% by volume, a silicone resin whose Si—H/alkenyl group ratio expressed in equation 1 described above is 0.45; at 30% by volume, boron nitride flakes whose crystal shape is hexagonal (D50 of 40 μm, aspect ratio of 10 to 30); at 20% by volume, aluminum nitride (D50 of 1.2 μm); at 20% by volume, spherical alumina particles (D50 of 2 μm); and at 1% by volume, zinc oxide particles (D50 of 0.1 μm).

### Comparative Example 4

In comparative example 4, a thermally conductive sheet was obtained using the same method as example 1 other than preparing a thermally conductive composition by uniformly mixing: at 39% by volume, a silicone resin whose Si—H/alkenyl group ratio expressed in equation 1 described above is 0.45; at 20% by volume, boron nitride flakes whose crystal shape is hexagonal (D50 of 40 μm, aspect ratio of 10 to 30); at 20% by volume, aluminum nitride (D50 of 1.2 μm); at 20% by volume, spherical alumina particles (D50 of 2 μm); and at 1% by volume, zinc oxide particles (D50 of 0.1 μm).

### Comparative Example 5

In comparative example 5, a thermally conductive sheet was obtained using the same method as example 1 other than preparing a thermally conductive composition by uniformly mixing: at 39% by volume, a silicone resin whose Si—H/alkenyl group ratio expressed in equation 1 described above is 0.45; at 20% by volume, boron nitride flakes whose crystal shape is hexagonal (D50 of 40 μm, aspect ratio of 10 to 30); at 10% by volume, aluminum nitride (D50 of 1.2 μm); at 30% by volume, spherical alumina particles (D50 of 2 μm); and at 1% by volume, zinc oxide particles (D50 of 0.1 μm).

### Comparative Example 6

In comparative example 6, a thermally conductive sheet was obtained using the same method as example 1 other than preparing a thermally conductive composition by uniformly mixing: at 39% by volume, a silicone resin whose Si—H/alkenyl group ratio expressed in equation 1 described above is 0.45; at 20% by volume, boron nitride flakes whose crystal shape is hexagonal (D50 of 40 μm, aspect ratio of 10 to 30); at 30% by volume, aluminum nitride (D50 of 1.2 μm); at 10% by volume, spherical alumina particles (D50 of 2 μm); and at 1% by volume, zinc oxide particles (D50 of 0.1 μm).

### Comparative Example 7

In comparative example 7, a thermally conductive sheet was obtained using the same method as comparative example 1 other than preparing a thermally conductive composition using boron nitride flakes whose crystal shape is hexagonal (D50 of 50 μm, aspect ratio of 15 to 40) instead of boron nitride flakes whose crystal shape is hexagonal (D50 of 40 μm, aspect ratio of 10 to 30).

### Comparative Example 8

In comparative example 8, a thermally conductive sheet was obtained using the same method as comparative example 2 other than preparing a thermally conductive composition using boron nitride flakes whose crystal shape is hexagonal (D50 of 50 μm, aspect ratio of 15 to 40) instead of boron nitride flakes whose crystal shape is hexagonal (D50 of 40 μm, aspect ratio of 10 to 30).

### Comparative Example 9

In comparative example 9, a thermally conductive sheet was obtained using the same method as comparative example 3 other than preparing a thermally conductive composition using boron nitride flakes whose crystal shape is hexagonal (D50 of 50 μm, aspect ratio of 15 to 40) instead of boron nitride flakes whose crystal shape is hexagonal (D50 of 40 μm, aspect ratio of 10 to 30).

### Comparative Example 10

In comparative example 10, a thermally conductive sheet was obtained using the same method as comparative example 4 other than preparing a thermally conductive composition using boron nitride flakes whose crystal shape is hexagonal (D50 of 50 μm, aspect ratio of 15 to 40) instead of boron nitride flakes whose crystal shape is hexagonal (D50 of 40 μm, aspect ratio of 10 to 30).

### Comparative Example 11

In comparative example 11, a thermally conductive sheet was obtained using the same method as comparative example 5 other than preparing a thermally conductive composition using boron nitride flakes whose crystal shape is hexagonal (D50 of 50 μm, aspect ratio of 15 to 40) instead of boron nitride flakes whose crystal shape is hexagonal (D50 of 40 μm, aspect ratio of 10 to 30).

### Comparative Example 12

In comparative example 12, a thermally conductive sheet was obtained using the same method as comparative example 6 other than preparing a thermally conductive composition using boron nitride flakes whose crystal shape is hexagonal (D50 of 50 μm, aspect ratio of 15 to 40) instead of boron nitride flakes whose crystal shape is hexagonal (D50 of 40 μm, aspect ratio of 10 to 30).

### <Oil Bleed Amount>

(A) in FIG. 4 is a sectional view illustrating a state in which the thermally conductive sheet 1 is interposed between compression jigs (upper jig 61 and lower jig 62). (B) in FIG. 4 is a plan view illustrating a state in which the thermally conductive sheet 1 is placed on the lower jig 62. (A) in FIG. 5 is a plan view illustrating the state in which the thermally conductive sheet 1 is interposed between the compression jigs (upper jig 61 and lower jig 62). (B) in FIG. 5 is a side view illustrating the state in which the thermally conductive sheet 1 is interposed between the compression jigs (upper jig 61 and lower jig 62).

A thermally conductive sheet 10, which is the thermally conductive sheet obtained in the examples and comparative examples processed to a size of 25 mm×25 mm, and a mesh 60 (product name: PET Mesh Sheet; product no.: TN180; made by Sanplatec) processed to a size of 40 mm×75 mm were prepared, and the weights of each were measured. The weights (g) of the thermally conductive sheets 10 (25 mm×25 mm×1 mm thick) prepared from the examples and comparative examples are listed in tables 1 and 2. The upper jig 61 and the lower jig 62 were prepared, and three filter papers 63 (model no.: Qualitative Filter Paper No. 101; diameter 90 mm) were placed stacked on the lower jig 62. Two meshes 60 were placed stacked on the filter papers 63, and the thermally conductive sheet 10 and a spacer 64 were placed on the meshes 60. As illustrated in (B) in FIG. 4, the interval between the thermally conductive sheet 10 and the spacer 64 was made to be approximately 1 cm. Two meshes 65 were placed stacked on the thermally conductive sheet 10 and the spacer 64. Three filter papers 66 were placed stacked on the meshes 65. The upper jig 61 was placed on the filter papers 66, and nuts 67 in four locations of the upper jig 61 were uniformly tightened until the thermally conductive sheet 10 entered a state of being compressed by 40%. With the thermally conductive sheet 10 interposed between the upper jig 61 and the lower jig 62 in the state of being compressed by 40%, the assembly was placed in an oven heated to 125° C. The thermally conductive sheet 10 interposed between the upper jig 61 and the lower jig 62 was removed 48 hours after being placed in the oven and then left standing at room temperature until cool. The nuts 67 in the four locations of the upper jig 61 were removed, and the weight was measured in a state in which the thermally conductive sheet 10 and the meshes 60 and 65 (four in total) are integrated. The bleed amount (g) of the silicone resin (binder resin) in the thermally conductive sheet 10 was found from the measured weight. The results are listed in tables 1 and 2.

### <Bulk Thermal Conductance>

For the bulk thermal conductance, the thermal resistance of each thermally conductive sheet was measured by a method conforming to ASTM-D5470. The thickness (mm) of the thermally conductive sheet at the time of measurement was plotted on the horizontal axis, the thermal resistance (° C.·cm²/W) of the thermally conductive sheet was plotted on the vertical axis, and the bulk thermal conductance (W/m·K) of the thermally conductive sheet was calculated from the slope of this plot. For the thermal resistance of the thermally conductive sheet, three types of thermally conductive sheets of the same formulation as the thermally conductive sheets of the examples and comparative examples but with different thicknesses were prepared, and measurements were taken for the thermally conductive sheets of the respective thicknesses. The results are listed in tables 1 and 2.

### <Effective Thermal Conductance>

The effective thermal conductance (W/m·K) of the thermally conductive sheet was measured using a thermal-resistance measurement device conforming to ASTM-D5470 by applying a load of 0.3 to 3 kgf/cm² to a 1 mm thick thermally conductive sheet, and the highest thermal conductance value was selected. The results are listed in tables 1 and 2.

### <Tack Force>

The obtained thermally conductive sheet was interposed between release-treated PET films and pressed for 30 seconds at 0.5 MPa. Afterward, the PET films were peeled from the thermally conductive sheet, and the thermally conductive sheet was again interposed between other release-treated PET films. This was left standing for seven days. After being left standing for seven days, the release-treated PET films were peeled from the thermally conductive sheet. Immediately afterward (within 3 minutes), using a tack tester (made by Malcom), the tack force (gf) of the surface of the thermally conductive sheet of when the thermally conductive sheet was pushed 50 μm at 2 mm/s and pulled out at 10 mm/s using a probe of a 5.1 mm diameter was found. The results are listed in tables 1 and 2.

### <Fixing to Aluminum Plate>

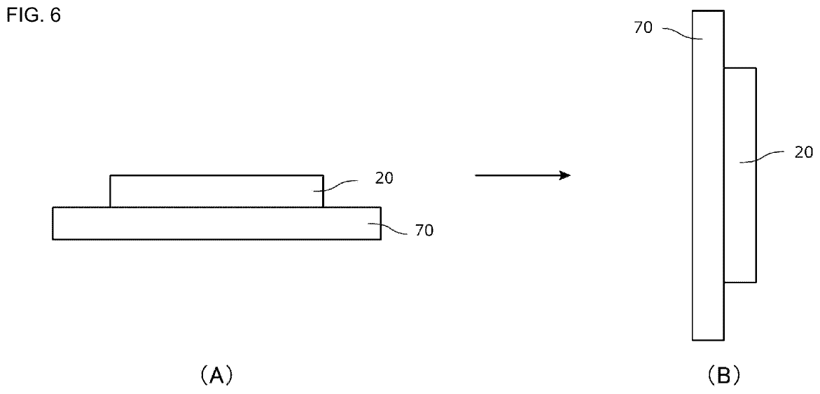

FIG. 6 is a diagram for describing a method of evaluating whether the thermally conductive sheet slides off when the thermally conductive sheet is placed on an aluminum plate and tilted 90°. As illustrated in (A) in FIG. 6, a thermally conductive sheet 20 was placed on an aluminum plate 70 placed horizontally. Afterward, as illustrated in (B) in FIG. 6, the aluminum plate 70 was tilted 90° while holding the thermally conductive sheet 20. Whether the thermally conductive sheet 20 slides off at this time was evaluated. The results are listed in tables 1 and 2. In tables 1 and 2, O indicates that the thermally conductive sheet 20 did not slide off (OK). In tables 1 and 2, x indicates that the thermally conductive sheet 20 slid off (NG).

### <Change in Thermal Resistance Value>

The change in the thermal resistance value (° C.·cm²/W) of the thermally conductive sheet was found as follows. First, the thermal resistance value in a state in which the thermally conductive sheet immediately after production is compressed by 10% relative to the initial thickness (initial thermal resistance value when compressed by 10%: first thermal resistance value) was measured. This thermally conductive sheet was left standing for 1,000 hours at 150° C. Afterward, the thermal resistance value in a state of being compressed by 10% relative to the thickness after being left standing for 1,000 hours at 150° C. (thermal resistance value after 150° C.×1,000 H when compressed by 10%: second thermal resistance value) was measured. From these first and second thermal resistance values, the amount of change (%) in the thermal resistance value when compressed by 10% between before and after leaving the thermally conductive sheet standing for 1,000 hours at 150° C. was found. The results are listed in tables 1 and 2.

<Compression Ratio at Load of 3 kgf/cm²>

The compression ratio (%) of the obtained thermally conductive sheet of when a load of 3 kgf/cm² is applied after leaving the thermally conductive sheet standing for 1,000 hours at 150° C. was measured. The results are listed in tables 1 and 2.

### <Change in Shore Hardness>

The Shore type OO hardness of the thermally conductive sheet was measured by a measurement method conforming to ASTM-D2240. Specifically, the Shore hardness of when ten 1 mm thick thermally conductive sheets immediately after production are stacked (initial Shore hardness) and the Shore hardness of when ten 1 mm thick thermally conductive sheets are stacked after being left standing for 1,000 hours at 150° C. were measured. The Shore hardness of the thermally conductive sheet was made to be the average value of measurement results from measuring a total of ten points on both surfaces (five points per surface) The results are listed in tables 1 and 2.

### <Breakdown Voltage>

The breakdown voltage of the thermally conductive sheet was measured using an ultra-high-voltage withstand tester (made by Keisoku Giken; 7473) under conditions of a 1 mm thick thermally conductive sheet, a voltage increase rate of 0.05 kV/s, and room temperature. The voltage at the time of breakdown was made to be the breakdown voltage (kV). The results are listed in tables 1 and 2.

TABLE 1

| | Ex. 1 | Ex. 2 | Ex. 3 | Ex. 4 | Ex. 5 | Ex. 6 | Ex. 7 | Ex. 8 | Ex. 9 | Ex. 10 |
|---|---|---|---|---|---|---|---|---|---|---|
| Si—H/alkenyl group ratio | 0.45 | 0.58 | 0.45 | 0.45 | 0.45 | 0.58 | 0.45 | 0.45 | 0.45 | 0.45 |
| (mol ratio) | | | | | | | | | | |
| Silicone resin [vol %] | 32 | 32 | 34 | 36 | 32 | 32 | 34 | 36 | 33 | 33 |
| Alumina (D50 = 2 μm) | 20 | 20 | 20 | 20 | 20 | 20 | 20 | 20 | 20 | 10 |
| [vol %] | | | | | | | | | | |
| Aluminum nitride | 20 | 20 | 20 | 20 | 20 | 20 | 20 | 20 | 20 | 30 |
| (D50 = 1.2 μm) | | | | | | | | | | |
| [vol %] | | | | | | | | | | |
| Zinc oxide | 1 | 1 | 1 | 1 | 1 | 1 | 1 | 1 | — | — |
| (D50 = 0.1 μm) | | | | | | | | | | |
| [vol %] | | | | | | | | | | |
| Boron nitride | 27 | 27 | 25 | 23 | — | — | — | — | 27 | 27 |
| (D50 = 40 μm) | | | | | | | | | | |
| [vol %] | | | | | | | | | | |
| Boron nitride | — | — | — | — | 27 | 27 | 25 | 23 | — | — |
| (D50 = 50 μm) | | | | | | | | | | |
| [vol %] | | | | | | | | | | |
| Filler total amount [vol %] | 68 | 68 | 66 | 64 | 68 | 68 | 66 | 64 | 67 | 67 |
| Weight of thermally | 1.47 | 1.47 | 1.46 | 1.45 | 1.47 | 1.47 | 1.46 | 1.45 | 1.47 | 1.45 |
| conductive sheet | | | | | | | | | | |
| (25 mm × 25 mm × | | | | | | | | | | |
| 1 mm thickness) [g] | | | | | | | | | | |
| Oil bleed amount [g] | 0.17 | 0.15 | 0.18 | 0.19 | 0.16 | 0.14 | 0.18 | 0.18 | 0.16 | 0.17 |
| Bulk thermal conductance | 11.3 | 11.4 | 10.5 | 9.9 | 12.3 | 13.1 | 11.3 | 10.6 | 11.3 | 11.4 |
| [W/m · K] | | | | | | | | | | |
| Effective thermal | 9.1 | 9.2 | 8.3 | 7.5 | 10.5 | 11.1 | 9.2 | 8.5 | 9.2 | 9.3 |
| conductance [W/m · K] | | | | | | | | | | |
| 1 mm thick | | | | | | | | | | |
| Tack force [gf] | 85 | 80 | 88 | 92 | 84 | 80 | 88 | 90 | 87 | 83 |
| Aluminum plate affixing | ∘ | ∘ | ∘ | ∘ | ∘ | ∘ | ∘ | ∘ | ∘ | ∘ |
| test | | | | | | | | | | |
| Initial thermal resistance | 1.05 | 1.05 | 1.19 | 1.27 | 0.92 | 0.88 | 1.04 | 1.16 | 1.05 | 1.05 |
| value when compressed by | | | | | | | | | | |
| 10% [° C. · cm²/W] | | | | | | | | | | |
| Thermal resistance value | 1.13 | 1.13 | 1.27 | 1.36 | 1.00 | 0.95 | 1.12 | 1.25 | 1.13 | 1.14 |
| after 150° C. × 1,000 H | | | | | | | | | | |
| when compressed by 10% | | | | | | | | | | |
| [° C. · cm²/W] | | | | | | | | | | |
| Change amount [%] of | 7.6 | 7.6 | 6.7 | 7.1 | 8.7 | 8.0 | 7.7 | 7.8 | 7.6 | 8.6 |
| thermal resistance value | | | | | | | | | | |
| when compressed by 10% | | | | | | | | | | |
| (after 150° C. × 1,000 H) | | | | | | | | | | |
| Compression ratio [%] at | 23 | 22 | 25 | 28 | 21 | 23 | 26 | 28 | 23 | 21 |
| load of 3 kgf/cm² (after | | | | | | | | | | |
| 150° C. × 1,000 H) | | | | | | | | | | |
| Initial Shore hardness | 53 | 55 | 51 | 48 | 57 | 52 | 51 | 49 | 53 | 58 |
| (Shore OO) | | | | | | | | | | |
| Shore hardness (Shore OO) | 74 | 77 | 71 | 68 | 80 | 75 | 70 | 69 | 75 | 81 |
| after 150° C. × 1,000 H | | | | | | | | | | |
| Breakdown voltage | 8.5 | 8.5 | 8.6 | 9.0 | 8.1 | 8.1 | 8.4 | 8.7 | 8.5 | 8.5 |
| [kV/mm] | | | | | | | | | | |

TABLE 2

| | Comp. | Comp. | Comp. | Comp. | Comp. | Comp. | Comp. | Comp. | Comp. | Comp. | Comp. | Comp. |
|---|---|---|---|---|---|---|---|---|---|---|---|---|
| | ex. 1 | ex. 2 | ex. 3 | ex. 4 | ex. 5 | ex. 6 | ex. 7 | ex. 8 | ex. 9 | ex. 10 | ex. 11 | ex. 12 |
| Si—H/alkenyl | 0.33 | 0.84 | 0.45 | 0.45 | 0.45 | 0.45 | 0.33 | 0.84 | 0.45 | 0.45 | 0.45 | 0.45 |
| group ratio | | | | | | | | | | | | |
| (mol ratio) | | | | | | | | | | | | |
| Silicone resin | 32 | 32 | 29 | 39 | 39 | 39 | 32 | 32 | 29 | 39 | 39 | 39 |
| [vol %] | | | | | | | | | | | | |
| Alumina | 20 | 20 | 20 | 20 | 30 | 10 | 20 | 20 | 20 | 20 | 30 | 10 |
| (D50 = 2 μm) | | | | | | | | | | | | |
| [vol %] | | | | | | | | | | | | |
| Aluminum nitride | 20 | 20 | 20 | 20 | 10 | 30 | 20 | 20 | 20 | 20 | 10 | 30 |
| (D50 = 1.2 μm) | | | | | | | | | | | | |
| [vol %] | | | | | | | | | | | | |
| Zinc oxide | 1 | 1 | 1 | 1 | 1 | 1 | 1 | 1 | 1 | 1 | 1 | 1 |
| (D50 = 0.1 μm) | | | | | | | | | | | | |
| [vol %] | | | | | | | | | | | | |
| Boron nitride | 27 | 27 | 30 | 20 | 20 | 20 | — | — | — | — | — | — |
| (D50 = 40 μm) | | | | | | | | | | | | |
| [vol %] | | | | | | | | | | | | |
| Boron nitride | — | — | — | — | — | — | 27 | 27 | 30 | 20 | 20 | 20 |
| (D50 = 50 μm) | | | | | | | | | | | | |
| [vol %] | | | | | | | | | | | | |
| Filler total amount | 68 | 68 | 71 | 61 | 61 | 61 | 68 | 68 | 71 | 61 | 61 | 61 |
| [vol %] | | | | | | | | | | | | |
| Weight of | 1.47 | 1.47 | 1.49 | 1.44 | 1.46 | 1.42 | 1.47 | 1.47 | 1.49 | 1.44 | 1.46 | 1.42 |
| thermally | | | | | | | | | | | | |
| conductive sheet | | | | | | | | | | | | |
| (25 mm × 25 mm × | | | | | | | | | | | | |
| 1 mm thickness) [g] | | | | | | | | | | | | |
| Oil bleed amount | 0.25 | 0.16 | 0.15 | 0.55 | 0.54 | 0.56 | 0.24 | 0.17 | 0.15 | 0.55 | 0.55 | 0.57 |
| [g] | | | | | | | | | | | | |
| Bulk thermal | 10.5 | 11.1 | 10.7 | 7.7 | 7.2 | 7.8 | 11.1 | 11.6 | 11.5 | 7.8 | 7.4 | 7.9 |
| conductance | | | | | | | | | | | | |
| [W/m · K] | | | | | | | | | | | | |
| Effective thermal | 8.5 | 9.2 | 8.9 | 6.1 | 5.7 | 6.5 | 9.1 | 9.7 | 9.4 | 6.4 | 6.1 | 6.8 |
| conductance | | | | | | | | | | | | |
| [W/m · K] | | | | | | | | | | | | |
| 1 mm thick | | | | | | | | | | | | |
| Tack force [gf] | 102 | 76 | 60 | 98 | 95 | 96 | 99 | 74 | 58 | 97 | 95 | 93 |
| Aluminum plate | ∘ | x | x | ∘ | ∘ | ∘ | ∘ | x | x | ∘ | ∘ | ∘ |
| affixing test | | | | | | | | | | | | |
| Initial thermal | 1.07 | 1.03 | 1.12 | 1.37 | 1.41 | 1.35 | 0.95 | 0.87 | 1.04 | 1.27 | 1.28 | 1.25 |
| resistance value | | | | | | | | | | | | |
| when compressed | | | | | | | | | | | | |
| by 10% | | | | | | | | | | | | |
| [° C. · cm²/W] | | | | | | | | | | | | |
| Thermal | 1.15 | 1.1 | 1.25 | 1.48 | 1.51 | 1.46 | 1.03 | 0.94 | 1.19 | 1.43 | 1.45 | 1.42 |
| resistance value | | | | | | | | | | | | |
| after 150° C. × | | | | | | | | | | | | |
| 1,000 H when | | | | | | | | | | | | |
| compressed by 10% | | | | | | | | | | | | |
| [° C. · cm²/W] | | | | | | | | | | | | |
| Change amount | 7.5 | 6.8 | 11.6 | 8.0 | 7.1 | 8.1 | 8.4 | 8.0 | 14.4 | 12.6 | 13.3 | 13.6 |
| [%] of thermal | | | | | | | | | | | | |
| resistance value | | | | | | | | | | | | |
| when compressed | | | | | | | | | | | | |
| by 10% (after | | | | | | | | | | | | |
| 150° C. × 1,000 H) | | | | | | | | | | | | |
| Compression ratio | 25 | 18 | 15 | 32 | 33 | 30 | 22 | 19 | 14 | 31 | 32 | 31 |
| [%] at load of | | | | | | | | | | | | |
| 3 kgf/cm² (after | | | | | | | | | | | | |
| 150° C. × 1,000 H) | | | | | | | | | | | | |
| Initial Shore | 49 | 61 | 69 | 44 | 44 | 47 | 55 | 63 | 71 | 46 | 46 | 47 |
| hardness | | | | | | | | | | | | |
| (Shore OO) | | | | | | | | | | | | |
| Shore hardness | 70 | 83 | 89 | 65 | 65 | 68 | 78 | 85 | 92 | 67 | 67 | 68 |
| (Shore OO) after | | | | | | | | | | | | |
| 150° C. × 1,000 H | | | | | | | | | | | | |
| Breakdown voltage | 8.4 | 8.4 | 7.5 | 9.3 | 9.3 | 9.3 | 8.1 | 8.1 | 6.9 | 9.0 | 9.0 | 9.0 |
| [kV/mm] | | | | | | | | | | | | |

The thermally conductive sheet obtained in examples 1 to 10 is made of a cured material of a composition containing: a binder resin, an anisotropically thermally conductive filler, and another thermally conductive filler and meets conditions 1 and 2 described above. It was understood that the sheet has excellent adhesion to a heat generator and can suppress excessive bleeding of the binder resin. The thermally conductive sheet obtained in examples 1 to 10 meets condition 3 described above. It was understood that the thermal conductivity is favorable.

It was understood that in the thermally conductive sheet obtained in examples 1 to 10, the amount of change of the thermal resistance value measured at a compression ratio of 10% after the sheet is left standing for 1,000 hours at 150° C. relative to the thermal resistance value measured at a compression ratio of 10% immediately after production is within 10%. It was understood that in the thermally conductive sheet obtained in examples 1 to 10, the compression ratio measured using a load of 3 kgf/cm² after the sheet is left standing for 1,000 hours at 150° C. is 20% or higher.

It was understood that in the thermally conductive sheet obtained in comparative examples 1, 4 to 7, and 10 to 12, condition 2 described above is not met and excessive bleeding of the binder resin cannot be suppressed.

It was understood that in the thermally conductive sheet obtained in comparative examples 2, 3, 8, and 9, condition 1 described above is not met and fixing to an aluminum plate is not favorable.

It was understood that in the thermally conductive sheet obtained in comparative examples 3 and 9 to 12, the amount of change of the thermal resistance value measured at a compression ratio of 10% after the sheet is left standing for 1,000 hours at 150° C. relative to the thermal resistance value measured at a compression ratio of 10% immediately after production is not within 10%. It was understood that in the thermally conductive sheet obtained in comparative examples 2, 3, 8, and 9, the compression ratio measured using a load of 3 kgf/cm² after the sheet is left standing for 1,000 hours at 150° C. is less than 20%.

### REFERENCE SIGNS LIST

1 thermally conductive sheet, 1A surface, 2 binder resin, 3 anisotropically thermally conductive filler, 4 other thermally conductive filler, 10 thermally conductive sheet, 20 thermally conductive sheet, 51 electronic component, 52 heat spreader, 53 heat sink, 52a main surface, 52b sidewall, 60 mesh, 61 upper jig, 62 lower jig, 63 filter paper, 64 spacer, 65 mesh, 66 filter paper, 67 nut, 70 aluminum plate

1. A thermally conductive sheet, comprising:
a cured material of a composition comprising: a binder resin, an anisotropically thermally conductive filler, and an additional thermally conductive filler other than the anisotropically thermally conductive filler,
wherein the thermally conductive sheet satisfies:
condition 1: a tack force of the thermally conductive sheet is 80 gf or higher; and
condition 2: a bleed amount of the binder resin is 0.20 g or less after the thermally conductive sheet, which has a size of 25 mm×25 mm and a thickness of 1 mm, is left standing for 48 hours at 125° C. in a state of being compressed by 40%.

2. The thermally conductive sheet of claim 1, wherein the binder resin is an addition-reaction silicone resin;
the addition-reaction silicone resin comprises a polyorganosiloxane having an alkenyl group in one molecule and an organohydrogenpolysiloxane having, in one molecule, a hydrogen atom directly bonded to a silicon atom; and
an amount ratio of the polyorganosiloxane and the organohydrogenpolysiloxane satisfies equation 1: number of moles of hydrogen atoms directly bonded to silicon atoms/number of moles of alkenyl groups=0.40 to 0.60.

3. The thermally conductive sheet of claim 1, wherein a content of the binder resin in the thermally conductive sheet is 30 to 38% by volume.

4. The thermally conductive sheet of claim 1, wherein a content of the anisotropically thermally conductive filler in the thermally conductive sheet is 22 to 29% by volume.

5. The thermally conductive sheet of claim 1,
wherein the anisotropically thermally conductive filler comprises boron nitride, and the additional thermally conductive filler comprises alumina, and optionally at least one of aluminum nitride, zinc oxide, and aluminum hydroxide.

6. The thermally conductive sheet of claim 1, wherein the anisotropically thermally conductive filler comprises boron nitride flakes, and the boron nitride flakes are oriented in a thickness direction of the thermally conductive sheet.

7. The thermally conductive sheet of claim 1, wherein the sheet further satisfies condition 3: a bulk thermal conductance of the thermally conductive sheet is 9.5 W/m·K or higher.

8. The thermally conductive sheet of claim 1, wherein an amount of change of a thermal resistance value measured at a compression ratio of 10% after the thermally conductive sheet is left standing for 1,000 hours at 150° C. relative to a thermal resistance value measured at a compression ratio of 10% immediately after production, is 10% or less.

9. The thermally conductive sheet of claim 1, wherein a compression ratio measured under a load of 3 kgf/cm² after the sheet is left standing for 1,000 hours at 150° C., is 20% or higher.

10. A method for producing a thermally conductive sheet, the method comprising:
preparing a thermally conductive composition comprising a binder resin, an anisotropically thermally conductive filler, and an additional thermally conductive filler other than the anisotropically thermally conductive filler;
extruding the thermally conductive composition;
curing the extruded thermally conductive composition such that a cured material having a pillar shape is obtained; and
cutting, in a direction substantially perpendicular to a length direction of the pillar shape, the cured material to a predetermined thickness to obtain the thermally conductive sheet,
wherein the thermally conductive sheet satisfies:
condition 1: a tack force of the thermally conductive sheet is 80 gf or higher; and
condition 2: a bleed amount of the binder resin is 0.20 g or less after the thermally conductive sheet, which has a size of 25 mm×25 mm and a thickness of 1 mm, is left standing for 48 hours at 125° C. in a state of being compressed by 40%.

11. The method of claim 10, wherein the binder resin is an addition-reaction silicone resin;
the addition-reaction silicone resin comprises a polyorganosiloxane having an alkenyl group in one molecule and an organohydrogenpolysiloxane having, in one molecule, a hydrogen atom directly bonded to a silicon atom; and
an amount ratio of the polyorganosiloxane and the organohydrogenpolysiloxane satisfies equation 1: number of moles of hydrogen atoms directly bonded to silicon atoms/number of moles of alkenyl groups=0.40 to 0.60.

12. The method of claim 10, wherein the sheet further satisfies condition 3: a bulk thermal conductance of the thermally conductive sheet is 9.5 W/m·K or higher.

13. An electronic device, comprising:
a heat generator;
a heat dissipator; and
the thermally conductive sheet of claim 1 interposed between the heat generator and the heat dissipator.
